(19) United States
(12) Patent Application Publication
(10) Pub. No.: US 2010/0090094 A1
(43) Pub. Date: Apr. 15, 2010

(54) Solid-state detector

(75) Inventor: Masaru Sato, Kanagawa-ken (JP)

Correspondence Address: AKERMAN SENTERFITT, 8100 BOONE BOULEVARD, SUITE 700, VIENNA, VA, 22182-2683, US

(73) Assignee: FUJIFILM Corporation, Tokyo (JP)

(21) Appl. No.: 12/588,386

(22) Filed: Oct. 14, 2009

(30) Foreign Application Priority Data
Oct. 15, 2008 (JP) 2008-266068

(51) Int. Cl. H01L 27/00

(52) U.S. Cl. 250/208.1

(57) ABSTRACT

In a solid-state detector including a plurality of linear electrodes for outputting signals that are arranged parallel to each other, a wireless signal processing unit that processes wireless signals received by at least one of the plurality of linear electrodes for outputting signals and that extracts data superposed on the wireless signals is connected to the at least one of the plurality of linear electrodes for outputting signals in such a manner that connection/disconnection to the at least one of the plurality of linear electrodes for outputting signals is switchable.

### BACKGROUND OF THE INVENTION

1. Field of the Invention

The present invention relates to a solid-state detector including a plurality of linear electrodes for outputting signals that are arranged parallel to each other. In the solid-state detector, image information is recorded as a static latent image, and an electric current corresponding to the static latent image is output from the plurality of linear electrodes for outputting signals by scanning the static latent image with readout light.

2. Description of the Related Art

In radiography for medical diagnosis or the like, various kinds of radiography apparatuses are proposed and practically used. In the radiography apparatuses, solid-state detectors (the main parts of the solid-state detectors are semiconductors) are used as radiographic image detection means. Radiation that has passed through subjects (patients) is detected by the solid-state detectors, and image signals representing radiographic images of the subjects are obtained.

As the solid-state detectors that are used in the aforementioned apparatuses, various types of solid-state detectors have been proposed. For example, when the solid-state detectors are classified based on charge generation process of converting radiation to charges, there are a light-conversion-type solid-state detector, a direct-conversion-type solid-state detector, and the like. In the light-conversion-type solid-state detector, fluorescence output from a phosphor by irradiation with radiation is detected at a photoconductive layer to obtain signal charges. The obtained signal charges are temporarily stored in a charge storage portion, and the stored charges are converted into image signals (electric signals) and output. In the direct-conversion-type solid-state detector, signal charges generated in a photoconductive layer by irradiation with radiation are collected by a charge collection electrode, and temporarily stored in a charge storage portion. Further, the stored charge is converted into electric signals and output. In this type of solid-state detectors, the photoconductive layer and the charge collection electrodes are major elements.

Further, when the solid-state detectors are classified based on charge readout process of reading out stored charges to the outsides of the solid-state detectors, there are a light-readout-type solid-state detector, an electric-readout-type solid-state detector, and the like. In the light-readout-type solid-state detector, readout light (electromagnetic waves for readout) is output to the solid-state detector to read out charges from the solid-state detector. In the electric-readout-type solid-state detector, a TFT (thin film transistor) connected to a charge storage portion of the solid-state detector, a CCD (charge coupled device), a CMOS (complementary metal oxide semiconductor) sensor or the like is used as described in U.S. Pat. No. 6,828,539.

Further, the applicant of the Japanese patent application from which the priority of the present application is claimed proposed an improved-direct-conversion-type solid-state detector in U.S. Pat. No. 6,268,614, and the like. The improved-direct-conversion-type solid-state detector is a solid-state detector of both direct-conversion type and light-readout-type. The improved-direct-conversion-type solid-state detector includes a photoconductive layer for recording, a charge transfer layer, and a photoconductive layer for readout, and these layers are deposited one on another in this order. The photoconductive layer for recording exhibits photoconductivity by irradiation with recording light (radiation, fluorescence generated by irradiation with radiation, or the like). The charge transfer layer substantially acts as an insulator for charges that have the same polarity with latent image charges, and substantially acts as a conductor for transfer charges that have a polarity opposite to the polarity of the latent image charges. The photoconductive layer for readout exhibits photoconductivity by irradiation with electromagnetic waves for readout. In the improved-direct-conversion-type solid-state detector, signal charges (latent image charges) that carry image information are stored at the interface (charge storage portion) between the photoconductive layer for recording and the charge transfer layer. Further, electrodes (a first electric conductive layer and a second electric conductive layer) are deposited on either side of the three layers deposited one on another. In this type of solid-state detectors, the photoconductive layer for recording, the charge transfer layer, and the photoconductive layer for readout are major elements.

In recent years, various kinds of cassettes for radiography in which solid-state detectors as described above are housed in small cases have been proposed. The cassettes for radiography are relatively thin, and sufficiently small to be carried. Therefore, for example, when a patient is not able to move or the like, a cassette for radiography is placed under a region to be radiographed of the patient while the patient remains lying on his/her bed. Further, radiography is performed by moving a radiation source to an opposite side of the patient so that the radiation source and the cassette for radiography face each other with the patient (region to be radiographed) therebetween. Therefore, highly flexible radiography is possible.

Further, there are also cassettes for radiography in which the cassettes for radiography are connected to external consoles at the time of radiography. Radiography information, such as patient ID's, is obtained from the external consoles. Further, after radiography, radiographic image data is set to the external consoles. As this type of cassettes for radiography, a cassette for radiography that can perform wireless communication with the external console has been proposed, as described in U.S. Patent Application Publication No. 20060280337.

However, in the cassette for radiography including the solid-state detector as described above, it was necessary to additionally install an antenna for wireless communication to make it possible to perform wireless communication with the external console. Therefore, the cost of the device became high.

### SUMMARY OF THE INVENTION

In view of the foregoing circumstances, it is an object of the present invention to provide a solid-state detector that can perform wireless communication at low cost.

A first solid-state detector of the present invention is a solid-state detector comprising:

a plurality of linear electrodes for outputting signals that are arranged parallel to each other, wherein image information is recorded as a static latent image, and an electric current corresponding to the static latent image is output from the plurality of linear electrodes for outputting signals by scanning the static latent image with readout light, and wherein a wireless signal processing means that processes wireless signals received by at least one of the plurality of linear electrodes for outputting signals and that extracts data superposed on the wireless signals is connected to the at least one of the plurality of linear electrodes for outputting signals in such a manner that connection/disconnection to the at least one of the plurality of linear electrodes for outputting signals is switchable.

A second solid-state detector of the present invention is a solid-state detector comprising:

a charge generation unit that generates charges by irradiation with radiation that carries a radiographic image;

a plurality of linear electrodes for outputting signals that are arranged parallel to each other; and

a plurality of linear electrodes for switching signals that are arranged parallel to each other in a direction perpendicular to a direction in which the plurality of linear electrodes for outputting signals extend, wherein charge storage portions that store charges generated in the charge generation unit are formed in such a manner to correspond to intersection positions of the plurality of linear electrodes for outputting signals and the plurality of linear electrodes for switching signals, and wherein a wireless signal processing means that processes wireless signals received by at least one of the plurality of linear electrodes for outputting signals and/or at least one of the plurality of linear electrodes for switching signals, and that extracts data superposed on the wireless signals is connected to the at least one of the plurality of linear electrodes for outputting signals and/or the at least one of the plurality of linear electrodes for switching signals in such a manner that connection/disconnection to the at least one of the plurality of linear electrodes for outputting signals and/or the at least one of the plurality of linear electrodes for switching signals is switchable.

In the first and second solid-state detectors of the present invention, the wireless signals processed by the wireless signal processing means may be in any type, such as UWB (Ultra Wide Band), Bluetooth, HiSWANa (High Speed Wireless Access Network type a), HiperLAN, wireless 1394, wireless USB, and wireless LAN.

According to the first solid-state detector of the present invention, a wireless signal processing means that processes wireless signals received by a linear electrode for outputting signals and that extracts data superposed on the wireless signals is connected to the linear electrode for outputting signals in such a manner that connection/disconnection to the linear electrode for outputting signals is switchable. In the first solid-state detector of the present invention, the linear electrode for outputting signals is used also as an antenna for wireless communication. Since the linear electrode for outputting signals that is ordinarily provided in the solid-state detector is used as the antenna, it is not necessary to provide an antenna as an additional element. Hence, low-cost wireless communication is possible.

According to the second solid-state detector of the present invention, a wireless signal processing means that processes wireless signals received by a linear electrode for outputting signals and/or a linear electrode for switching signals and that extracts data superposed on the wireless signals is connected to the linear electrode for outputting signals and/or the linear electrode for switching signals in such a manner that connection/disconnection to the linear electrode for outputting signals and/or the linear electrode for switching signals is switchable. In the second solid-state detector of the present invention, the linear electrode for outputting signals and/or the linear electrode for switching signals is used also as an antenna for wireless communication. Since the linear electrode for outputting signals and the linear electrode for switching signals that are ordinarily provided in the solid-state detector are used, it is not necessary to provide an antenna as an additional element. Hence, low-cost wireless communication is possible.

### BRIEF DESCRIPTION OF THE DRAWINGS

FIG. 1 is a schematic diagram illustrating an example of a radiography system using a solid-state detector of the present invention;

FIG. 2 is a schematic diagram illustrating the configuration of a cassette for radiography in the radiography system;

FIG. 3 is a schematic diagram illustrating the structure of a solid-state detector in the cassette for radiography; and

FIG. 4 is a schematic diagram illustrating the configuration of the solid-state detector and a wireless signal processing unit.

### DESCRIPTION OF THE PREFERRED EMBODIMENTS

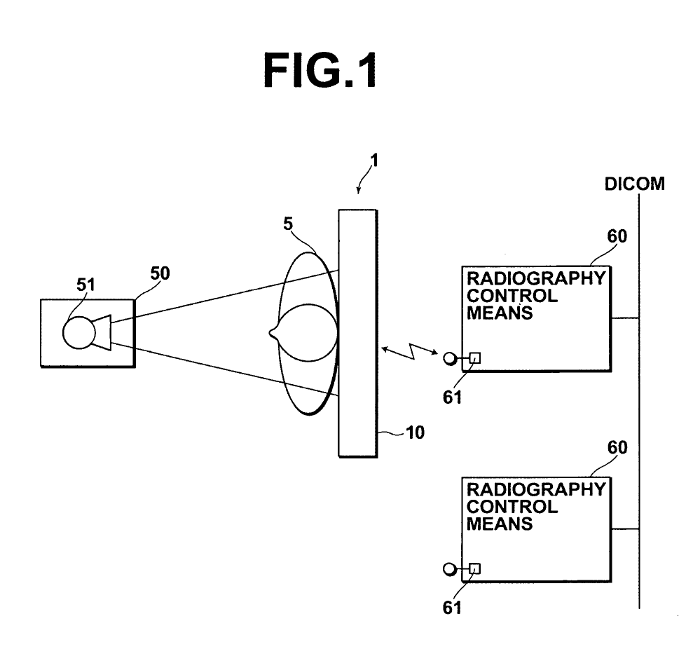

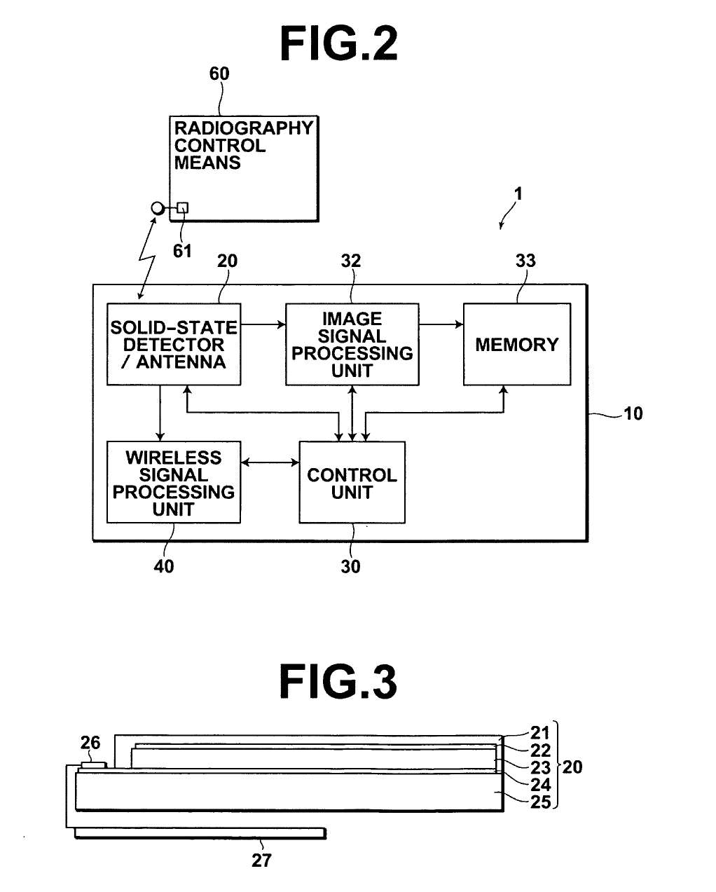

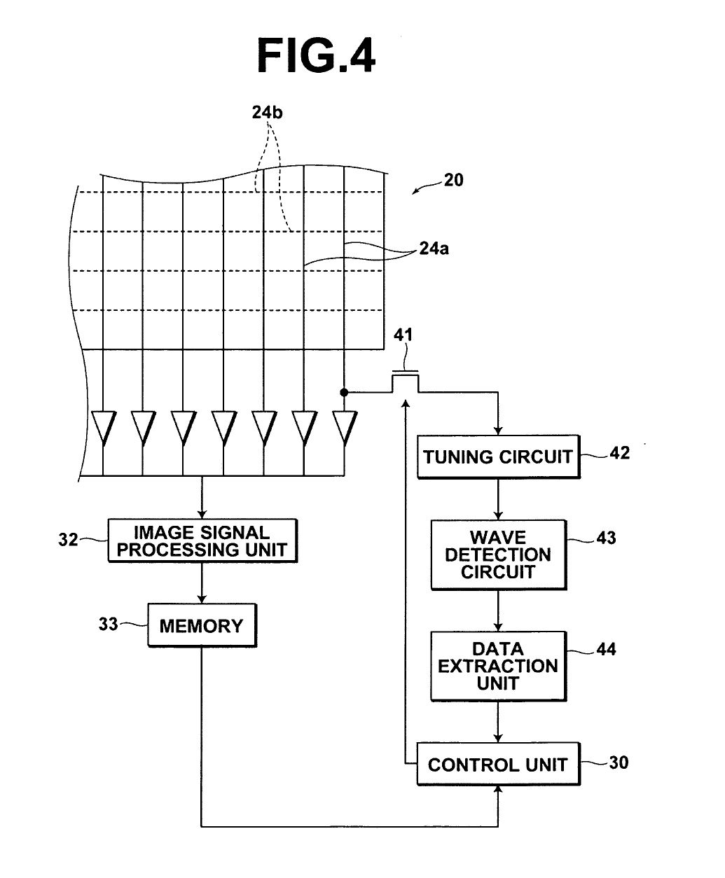

Hereinafter, embodiments of the present invention will be described with reference to drawings. FIG. 1 is a schematic diagram illustrating an example of a radiography system using a solid-state detector of the present invention. FIG. 2 is a schematic diagram illustrating the configuration of a cassette for radiography in the radiography system. FIG. 3 is a schematic diagram illustrating the structure of a solid-state detector in the cassette for radiography. FIG. 4 is a schematic diagram illustrating the configuration of the solid-state detector and a wireless signal processing unit.

This radiography system includes a cassette 1 for radiography, a radiation irradiation apparatus 50, and a radiography control means (console) 60. The cassette 1 for radiography includes a solid-state detector 20 and the like. The radiation irradiation apparatus 50 includes a radiation source 50 that outputs radiation toward the cassette 1 for radiography. The radiography control means (console) 60 controls radiography with respect to the cassette 1 for radiography, and the like.

The radiography control means 60 controls radiography with respect to the cassette 1 for radiography based on an instruction input by a person (radiographer) who performs radiography. Further, the radiography control means 60 obtains image signals from the cassette 1 for radiography. The radiography control means 60 includes a communication means 61 for communicating with the cassette 1 for radiography. The radiography control means 60 is connected to a network, such as DICOM (Digital Imaging and Communication in Medicine).

As illustrated in FIG. 2, the solid-state detector 20, an image signal processing unit 32, a memory 33, a wireless signal processing unit 40, a power source, which is not illustrated, a control unit 30, and the like are housed in a case 10 of the cassette 1 for radiography. The solid-state detector 20 is an imaging device. The image signal processing unit 32 processes signals output from the solid-state detector 20. The memory 33 stores image information. The wireless signal processing unit 40 processes wireless signals received by the solid-state detector 20, and extracts data superposed on the wireless signals. The power source supplies power to each unit (element), and the control unit 30 controls operation of each unit.

As illustrated in FIGS. 3 and 4, the solid-state detector 20 includes a first electric conductive layer 24, a photoconductive layer 23, a second electric conductive layer 22, and an insulation layer 21. These layers are provided on a glass substrate 25, and deposited one on another in this order. The first electric conductive layer 24 includes a-Si TFT's, and the photoconductive layer 23 generates charges by irradiation with radiation, and exhibits conductivity.

The first electric conductive layer 24 includes a plurality of electrodes 24a for outputting signals and a plurality of electrodes 24b for switching signals. Further, a TFT is formed in such a manner to correspond to each pixel. An output from each TFT is connected to an IC chip 26 through the linear electrode 24a for outputting signals, and the IC chip 26 is connected to the image signal processing unit 32 on a printed circuit board (substrate) 27.

In the solid-state detector 20, when the photoconductive layer 23 is irradiated with radiation while an electric field is generated between the first electric conductive layer 24 and the second electric conductive layer 22, pairs of charges (dipoles) are generated in the photoconductive layer 23. Further, latent image charges corresponding to the amount of the pairs of charges are stored in the first electric conductive layer 24. When the stored latent image charges are read out, the TFT's in the first electric conductive layer 24 are sequentially driven to output an analog signal corresponding to the latent image charge for each pixel. Further, the analog signal for each pixel is detected by the image signal processing unit 32, and the detected analog signal for each pixel is compounded (combined) in the arrangement order of the pixels. Further, AD (analog to digital) conversion is performed on the compounded analog signals by an AD conversion unit (not illustrated) to generate digital image signals. The generated digital image signals are stored in the memory 33.

Further, as illustrated in FIG. 4, the wireless signal processing unit 40 is connected to an outermost linear electrode 24a for outputting signals, which is positioned at an end of the plurality of linear electrode 24a for outputting signals, in the first electric conductive layer 24. The wireless signal processing unit 40 is connected to the outermost linear electrode 24a for outputting signals in such a manner that connection/disconnection to the outermost linear electrode 24a is switchable. The wireless signal processing unit 40 processes the wireless signals received by the outermost linear electrode 24a for outputting signals, and extracts data superposed on the wireless signals. Specifically, the outermost linear electrode 24a for outputting signals functions also as antenna for wireless communication.

The wireless signal processing unit 40 includes a switch 41, a tuning circuit 42, a wave detection circuit 43, and a data extraction unit 44. The tuning circuit 42 selects only signals of a predetermined frequency, and the wave detection circuit 43 restores the wireless signals to original transmission signals. The data extraction unit 44 converts the transmission signals into digital data.

Here, the switch 41 switches connection/disconnection of downstream-side circuits (units) that are provided after the switch 41 in the wireless signal processing unit 40. When wireless communication is performed with the radiography control means 60, the switch 41 is turned on (ON state). Wireless signals received by the linear electrode 24a for outputting signals are input to the downstream-side circuits that are provided after the switch 41 in the wireless signal processing unit 40. When image signals are read out from the solid-state detector 20, the switch 41 is turned off (OFF state), and the control unit 30 controls so that the analog signals output from the linear electrodes 24a for outputting signals are input to the image signal processing unit 32. The switch 41 is kept turned on except when the image signals are read out from the solid-state detector 20. Therefore, wireless communication with the radiography control means 60 is possible except when the image signals are read out from the solid-state detector 20.

The wireless communication system may be any type, such as UWB (Ultra Wide Band), Bluetooth, HiSWANa (High Speed Wireless Access Network type a), HiperLAN, wireless 1394, wireless USB, and wireless LAN.

Further, to improve the sensitivity of communication, it is desirable that the frequency of communication is selected in such a manner that the wavelength is the same as or the twice the length of the linear electrode 24a for outputting signals. For example, the length of a side (edge) of a general solid-state detector 20 that is used in chest radiography (chest X-rays) or the like is 43 cm. In other words, the length of the linear electrode 24a for outputting signals is 43 cm. In this case, it is desirable that 680 MHz or 340 MHz is selected as the frequency of communication. When the frequency is 680 MHz, the wavelength is the same as the length of the linear electrode 24a for outputting signals. When the frequency is 340 MHz, the wavelength is twice the length of the linear electrode 24a for outputting signals.

Next, the operations of the radiography system will be described. All of the operations in the cassette 1 for radiography are controlled by the control unit 30.

The switch 41 of the wireless signal processing unit 40 connected to the solid-state detector 20 is ordinarily kept turned on. Therefore, wireless communication with the radiography control means 60 is possible.

The radiography control means 60 constantly sends communication identification signals for establishing communication with a terminal equipment, such as the cassette 1 for radiography. When the cassette 1 for radiography receives the communication identification signal, the cassette 1 for radiography sends a response signal to establish communication with the equipment (radiography communication means 60) that has sent the communication identification signal, and establishes communication with the radiography communication mans 60.

When communication between the cassette 1 for radiography and the radiography control means 60 are established as described above, and the radiographer (operator) inputs information that radiography should be performed, a radiography request signal is sent from the radiography control means 60 to the cassette 1 for radiography.

When the cassette 1 for radiography receives the radiography request signal, the cassette 1 for radiography sends a radiography ready signal to the radiography control means 60. When the radiography control means 60 receives the radiography ready signal, the radiography control means 60 sends a radiography start signal to the cassette 1 for radiography.

When the cassette 1 for radiography receives the radiography start signal, voltage is applied to the solid-state detector 20.

In this state, when the radiographer presses an irradiation switch (button) of the radiation irradiation apparatus 50, radiation is output from the radiation source 51 toward the cassette 1 of radiography.

When the cassette 1 for radiography is irradiated with radiation, latent image charges that carry radiographic image information are stored in the solid-state detector 20. The amount of the stored latent image charges is substantially proportional to the radiation dose that has passed through the subject (patient) 5. Therefore, the latent image charges carry a static latent image.

In the cassette 1 for radiography, application of voltage to the solid-state detector 20 is stopped after a predetermined time period has passed to end radiography. After the radiography is ended, the switch 41 is turned off, and analog signals corresponding to the latent image charges are output from the solid-state detector 20. Further, AD conversion is performed on the analog signals at the image signal processing unit 32, and digital image signals are generated. The digital image signals generated by the image signal processing unit 32 are sequentially output to the memory 33 in the order of generation of the digital image signals.

When all of the digital image signals have been transferred to the memory 33, the switch 41 is turned on again, and an image transfer request signal is sent to the radiography control means 60. When the radiography control means 60 receives the image transfer request signal, the radiography control means 60 sends an image transfer ready signal to the cassette 1 for radiography.

When the cassette 1 for radiography receives the image transfer ready signal, the cassette 1 for radiography sequentially sends the image signals stored in the memory 33 to the radiography control means 60. After the image signals are sent, the series of processing ends.

So far, the embodiments of the present invention have been described. However, the present invention is not limited the aforementioned embodiments. For example, the number of the linear electrode or electrodes for outputting signals connected to the wireless signal processing unit is not limited to one. For example, a plurality of linear electrodes for outputting signals may be connected to the wireless signal processing unit, and diversity transmission/receipt operation may be performed. Further, it is not necessary that the wireless signal processing unit is connected to the linear electrode for outputting signals. The wireless signal processing unit may be connected to a linear electrode (electrodes) for switching signals instead of the linear electrode (electrodes) for outputting signals.

Further, the solid-state detector may be a light-readout-type solid-state detector.

Further, the present invention is applicable not only to a solid-state detector that mainly detects radiation. The present invention may be applied to various kinds of devices, such as a CCD and a liquid crystal monitor, as long as the devices have linear electrodes.

What is claimed is:

1. A solid-state detector comprising:
a plurality of linear electrodes for outputting signals that are arranged parallel to each other, wherein image information is recorded as a static latent image, and an electric current corresponding to the static latent image is output from the plurality of linear electrodes for outputting signals by scanning the static latent image with readout light, and wherein a wireless signal processing means that processes wireless signals received by at least one of the plurality of linear electrodes for outputting signals and that extracts data superposed on the wireless signals is connected to the at least one of the plurality of linear electrodes for outputting signals in such a manner that connection/disconnection to the at least one of the plurality of linear electrodes for outputting signals is switchable.

2. A solid-state detector comprising:
a charge generation unit that generates charges by irradiation with radiation that carries a radiographic image;
a plurality of linear electrodes for outputting signals that are arranged parallel to each other; and
a plurality of linear electrodes for switching signals that are arranged parallel to each other in a direction perpendicular to a direction in which the plurality of linear electrodes for outputting signals extend, wherein charge storage portions that store charges generated in the charge generation unit are formed in such a manner to correspond to intersection positions of the plurality of linear electrodes for outputting signals and the plurality of linear electrodes for switching signals, and wherein a wireless signal processing means that processes wireless signals received by at least one of the plurality of linear electrodes for outputting signals and/or at least one of the plurality of linear electrodes for switching signals, and that extracts data superposed on the wireless signals is connected to the at least one of the plurality of linear electrodes for outputting signals and/or the at least one of the plurality of linear electrodes for switching signals in such a manner that connection/disconnection to the at least one of the plurality of linear electrodes for outputting signals and/or the at least one of the plurality of linear electrodes for switching signals is switchable.
